(19) United States
(12) Patent Application Publication
(10) Pub. No.: US 2013/0214801 A1
(43) Pub. Date: Aug. 22, 2013

(54) Pressure-based Fingerprint Authentication Device

(71) Applicant: Hsu-Feng Hsiao, Shanghai (CN)

(72) Inventor: Hsu-Feng Hsiao, Shanghai (CN)

(73) Assignee: JP SENSOR CORPORATION, Kowloon (HK)

(21) Appl. No.: 13/399,134

(22) Filed: Feb. 17, 2012

(51) Int. Cl. G01R 27/08

(52) U.S. Cl. 324/692

(57) ABSTRACT

A method and apparatus for sensing a fingerprint has an array of sensors, each sensor having a sensing surface for receiving the pressure of a finger and having an ITO layer that has an intrinsic variable resistance characteristic that varies because of the varying ridges and valleys of a finger. The intrinsic variable resistance characteristic is converted to a variable voltage for a given pixel based on the pressure applied by the finger, and the fingerprint is determined based on the variable voltage readings for each pixel.

### BACKGROUND OF THE INVENTION

1. Field of the Invention

The present invention relates to apparatus for identification of fingerprints. In particular, this invention relates to a sensor for sensing a fingerprint in order to enter corresponding electrical information into a fingerprint authentication device. Still more particularly, this invention relates to a fingerprint authentication device having a surface for pressing a finger thereto and having pressure-sensitive means for reading the ridges and valleys of the finger when pressed against the sensing surface.

2. Description of the Prior Art

In a fingerprint sensor, the finger under investigation is usually pressed against a flat surface, such as one side of a glass plate, and the ridge-valley pattern of the finger tip is sensed by some sensing element such as an interrogating light beam if a laser technique is used.

Fingerprint authentication devices of this nature are generally used to control the access of individuals to information (information access control), for instance, computer terminals, or to buildings (physical access control).

One of the problems associated with fingerprint sensors concerns the reliable and accurate transformation of the ridge-valley pattern of the finger tip into electrical signals. Optical techniques which are widely used require a high amount of sophisticated equipment. Simple electromechanical sensors are sometimes not sensitive enough.

The condition of the finger can also attribute to inaccurate readings. For example, certain sensors may not accurately read a wet, oily or dirty finger that is pressed on the sensor. Also, the speed at which a finger is slid on to the sensor may impact the accuracy of the reading.

One form of sensor that has been used is a capacitive sensor, as described in U.S. Pat. No. 4,353,056 to Tsikos, where the sensing member contains a plurality of small capacitors. When a finger is pressed against the sensing surface, the capacitances of the capacitors are locally changed in accordance with the ridges and the valleys. The information about the capacitance distribution is transformed into an electrical signal that is used for processing. Unfortunately, the sensitivity of capacitors may still be insufficient to ensure accurate reading and authentication of fingerprints under all circumstances.

Therefore, there is a need for a fingerprint sensor which is adapted to reliably sense the fingerprint relief and transform the sensed information into electrical signals.

### SUMMARY OF THE DISCLOSURE

In order to accomplish the objectives of the present invention, the present invention provides a fingerprint authentication device having a sensor which uses variable voltage to detect the ridge-valley pattern of a finger tip. The variable voltage for each pixel in an array is obtained by the intrinsic variable resistance characteristic of an indium-tin-oxide (ITO) layer based on the pressure applied by the finger.

The fingerprint authentication device according to one embodiment of the present invention has an array of sensors, each comprising an E-sheet having a sensing surface for receiving the pressure of a finger, a TFT pixel spaced from the E-sheet and having an ITO layer that has an intrinsic variable resistance characteristic that varies because of the varying ridges and valleys of a finger, and means coupled to the TFT pixel for converting the intrinsic variable resistance characteristic to a variable voltage for a given pixel based on the pressure applied by the finger. The device further includes means for determining the fingerprint based on the variable voltage readings for each pixel.

### BRIEF DESCRIPTION OF THE DRAWINGS

FIG. 1 is an electrical diagram illustrating an array of sensors for use in detecting a fingerprint according to one embodiment of the present invention.

FIG. 2 is a single fingerprint sensor according to the present invention.

FIG. 3 is a diagram of the structure of a silicon TFT pixel according to the present invention.

FIG. 4 illustrates the operation of the fingerprint sensor of FIG. 2.

### DETAILED DESCRIPTION OF THE PREFERRED EMBODIMENTS

The following detailed description is of the best presently contemplated modes of carrying out the invention. This description is not to be taken in a limiting sense, but is made merely for the purpose of illustrating general principles of embodiments of the invention. The scope of the invention is best defined by the appended claims.

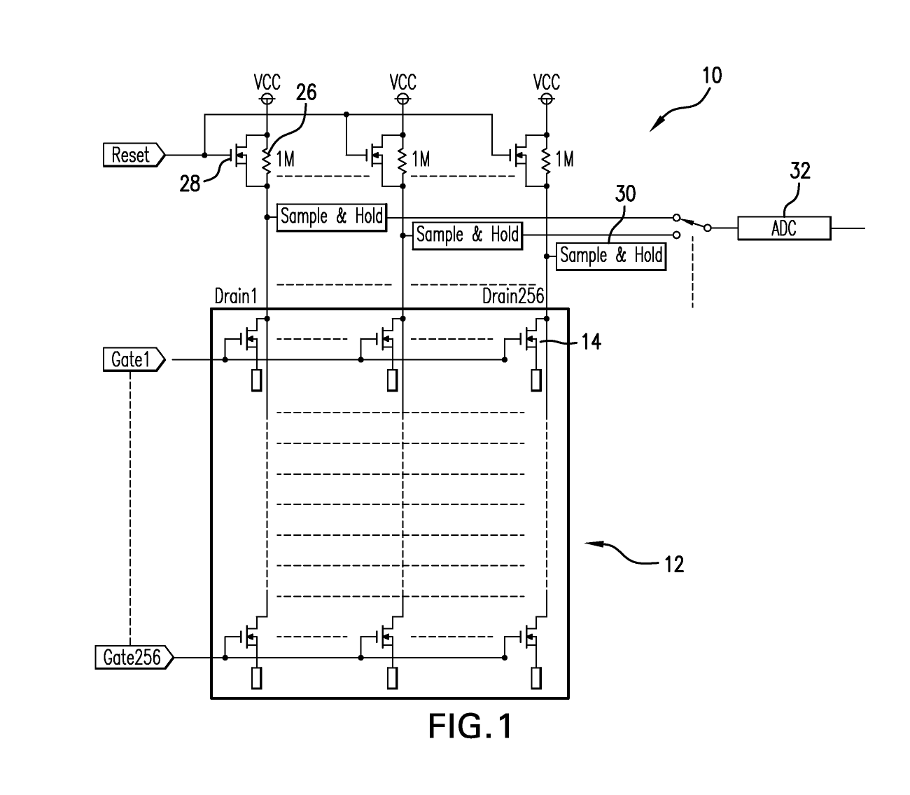

According to FIG. 1, the fingerprint authentication device 10 according to the present invention contains a two-dimensional array 12 of sensors 14. In one non-limiting embodiment of the present invention, the array 12 can be comprised of 256×256 sensors 14.

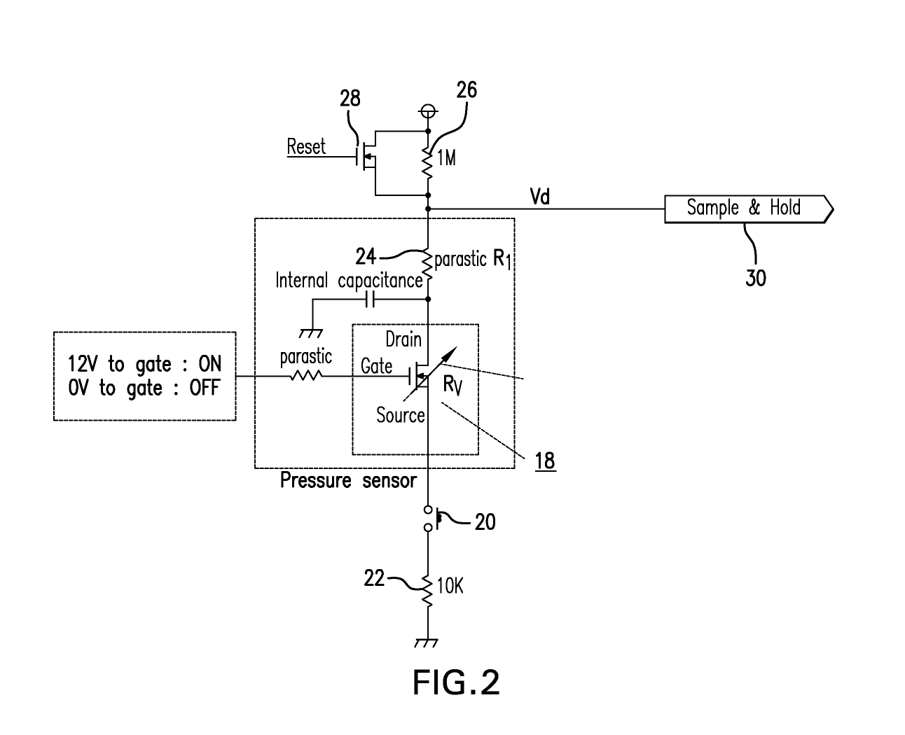

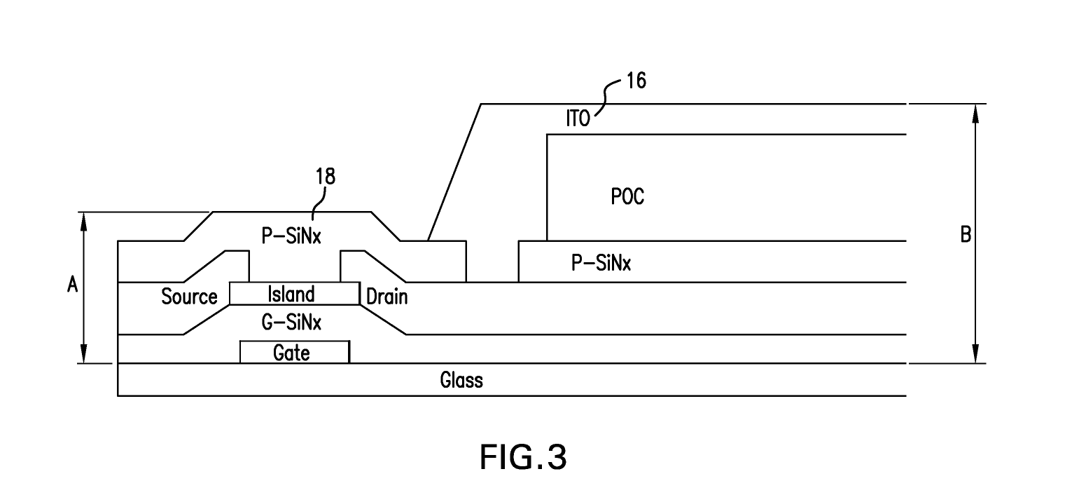

FIGS. 2 and 3 illustrate a single sensor 14 of the array 12. The finger F is adapted to be pressed on an E-sheet 20 layer that is spaced from an ITO (indium-tin-oxide) layer 16. The E-sheet 20 represents a flat sensing surface. The circuit of the sensor 14 includes a silicon TFT (thin-film-transistor) pixel 18. FIG. 3 is a diagram of the structure of a single silicon TFT pixel 18. The thickness between B and A is less than or equal to 1 micrometer. The TFT pixel 18 has a drain that is coupled to the ITO layer 16, and a source that is coupled to the E-sheet 20. As such, the E-sheet 20 behaves as a switch that connects the source to ground via a 10 k ohm resistor.

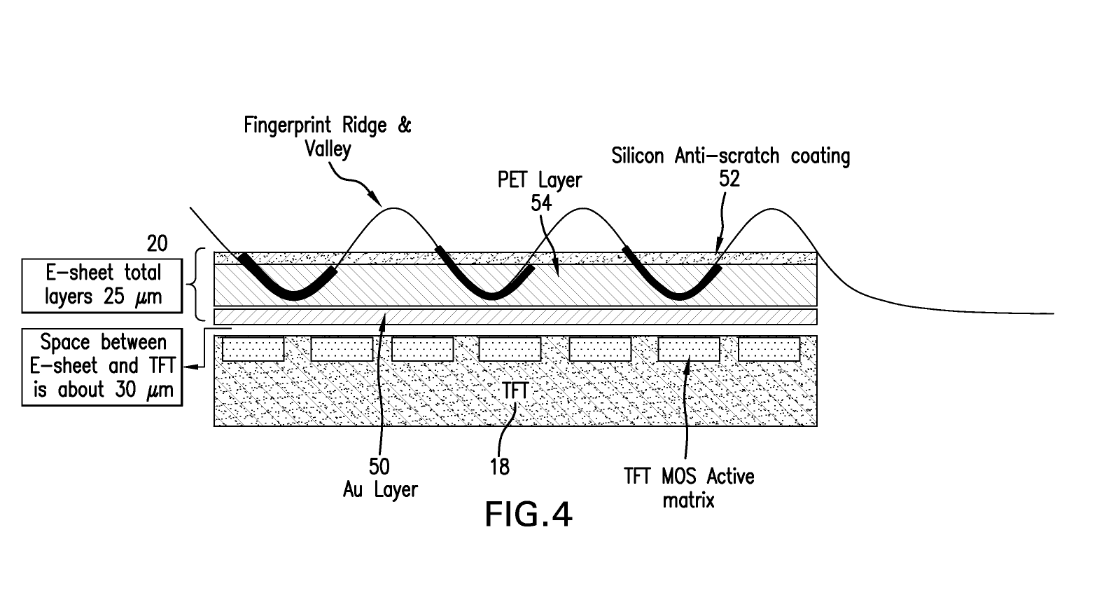

Referring to FIG. 4, the E-sheet 20 is comprised of three layers, which when combined is preferably soft and flexible enough to conform to the ridges and valleys of a fingerprint. The E-sheet 20 includes a bottom layer 50 that directly faces the TFT pixel 18, a top layer 52 that is adapted to contact a finger, and a middle layer 54. In the preferred embodiment, the bottom layer 50 is a very flexible Au (gold) layer, the middle layer 54 is a flexible PET layer, and the top layer 52 is a silicon anti-scratch coating. The combined thickness of the three layers 50, 52, 54 is about 25 micrometers. The spacing between the bottom layer 50 and the TFT pixel 18 is about 30 micrometers.

Referring back to FIG. 2, a current-limiting resistor 22 is positioned between the E-sheet 20 and ground. In addition, the TFT pixel 18 is driven by a 12V voltage that is applied to the gate of the TFT pixel 18. FIG. 2 illustrates a parasitic resistor, which is actually the intrinsic impedance of the TFT gate, and not an actual resistor. The current at the gate of the TFT pixel 18 varies depending on the finger pressure applied to the E-sheet 20, and the current is proportional to the pressure. An intrinsic resistance Rv is generated at the gate of the TFT pixel 18.

A voltage divider is formed by the resistors 22, 24 and 26, and the TFT pixel 18(Rv), with the resulting voltage Vd provided to a sample-and-hold (S/H) circuit 30. A gate 28 is provided for the reset circuit. When the gate 28 is on, the gate 28 forms a short between its “source” and “drain”, thereby providing a path to set the point where the S/H circuit 30 is to the initial voltage. The resistor 24 is coupled to the drain of the gate of the TFT pixel 18. The resistor 24 is actually an intrinsic impedance of the gate of the TFT pixel 18, and not an actual resistor.

The ITO layer 16 turns out the characteristics of the ITO layer's variable resistance (which is proportional to pressure), which is then converted to a (variable) voltage reading, and then converted from analog to digital format so that the resulting digital signals can be processed by an MCU (processor) (not shown) to determine the fingerprint.

FIGS. 2 and 4 illustrate the operational concept of the present invention, which uses the intrinsic resistance characteristic of the ITO layer 16 to obtain a voltage reading that varies because of the varying ridges and valleys of a fingerprint. In this regard, the TFT pixel 18 can be viewed as generating an intrinsic resistance Rv which can also be represented by the notation R(drain+source). Then, the RC's equivalent circuit is formed by the internal capacitance times R(total), where:

V(s&h)=(Rv+10 K+R1)/(Rv+10 K+R1+1 M)

R(total)=(R1+1 M)//(Rv+10 K)≈(Rv+10 K), since 1 M is comparatively huge and hence can be ignored.

Thus, the E-sheet 20 actually behaves as an on-off switch for the TFT pixel 18, so that the imposed pressure on the TFT pixel 18 results in a resistance that is proportional to it, which turns out to be the V(s&h) with a R(total)×C discharge time constant.

As illustrated by FIG. 1, the fingerprint authentication device 10 scans the array 12 using a well-known recursive X-axis and Y-axis scan to detect the pressure at each sensor 14. The analog signal from each sensor 14 is then provided to a plurality of S/H circuits 30 in the form of a voltage. The S/H circuits are coupled to an ADC (ahalog-to-digital converter) 32 that converts the analog signals to 8-bit grey scale digital signals. Since the surface and patterns of a fingerprint are not flat, the grey scale can sense the light and dark areas of a finger's pattern. These digital signals can be stored in a memory (not shown) of the device 10. The information contained in these digital signals represents the fingerprint. If desired, the information stored in the memory can be read out, and can also be displayed on a display device, such as a screen, printed out, or plotted on a chart.

While the description above refers to particular embodiments of the present invention, it will be understood that many modifications may be made without departing from the spirit thereof. The accompanying claims are intended to cover such modifications as would fall within the true scope and spirit of the present invention.

What is claimed is:

1. A fingerprint authentication device comprising:
an array of sensors, each sensor comprising:
an E-sheet having a sensing surface for receiving the pressure of a finger;
a TFT pixel spaced from the E-sheet and having an ITO layer that has an intrinsic variable resistance characteristic that varies because of the varying ridges and valleys of a finger; and
means coupled to the TFT pixel for converting the intrinsic variable resistance characteristic to a variable voltage for a given pixel based on the pressure applied by the finger; and
means for determining the fingerprint based on the variable voltage readings for each pixel.

2. The device of claim 1, wherein the converting means includes a voltage divider and a plurality of sample-and-hold circuits.

3. The device of claim 1, wherein the E-sheet operates as a switch.

4. The device of claim 1, wherein the E-sheet comprises a bottom layer that directly faces the TFT pixel, a top layer, and a middle layer, wherein the bottom layer is a flexible Au (gold) layer, the middle layer is a flexible PET layer, and the top layer is a silicon anti-scratch coating.

5. The device of claim 4, wherein the three layers of the E-sheet has a combined thickness of about 25 micrometers.

6. The device of claim 1, wherein the spacing between the E-sheet and the TFT pixel is about 30 micrometers.

7. A method of sensing a fingerprint, comprising the steps of:
providing an array of sensors, each sensor having a sensing surface for receiving the pressure of a finger and having an ITO layer that has an intrinsic variable resistance characteristic that varies because of the varying ridges and valleys of a finger;
converting intrinsic variable resistance characteristic to a variable voltage for a given pixel based on the pressure applied by the finger; and
determining the fingerprint based on the variable voltage readings for each pixel.
